(19) United States
(12) Patent Application Publication
(10) Pub. No.: US 2015/0270291 A1
(43) Pub. Date: Sep. 24, 2015

(54) Array Substrate, Method for Preparing the Same and Display Device

(71) Applicants: BOE TECHNOLOGY GROUP CO., LTD., Beijing (CN); BEIJING BOE DISPLAY TECHNOLOGY CO., LTD., Beijing (CN)

(72) Inventors: Chuan TIAN, Beijing (CN); Wei XU, Beijing (CN); Yong WANG, Beijing (CN); Guohong LI, Beijing (CN)

(21) Appl. No.: 14/444,355

(22) Filed: Jul. 28, 2014

(30) Foreign Application Priority Data
Mar. 20, 2014 (CN) 201410105759.6

(51) Int. Cl. H01L 27/12; H01L 29/786; H01L 21/56; G02F 1/1368; H01L 23/29; H01L 23/522; H01L 23/31; H01L 29/66; H01L 21/768

(52) U.S. Cl. CPC H01L 27/1244; H01L 27/127; H01L 27/1248; H01L 29/66742; H01L 29/78609; H01L 21/56; H01L 21/76802; H01L 23/291; H01L 23/5226; H01L 23/3171; H01L 21/76885; G02F 1/1368

(57) ABSTRACT

The present invention provides an array substrate and method for preparing the same, and a display device. The array substrate comprises: a display area and a non-display area, and a plurality of signal connection wires located in the non-display area for connecting driver units, the signal connection wires comprising first connection wires electrically connected with the driver units and second connection wires electrically connected with the first connection wires, the second connection wires being arranged at least in two layers, and each layer of the second connection wires being insulated from one another.

### CROSS-REFERENCE TO RELATED APPLICATION

This application claims priority to Chinese Patent Application No. 201410105759.6 filed on Mar. 20, 2014, the disclosures of which are incorporated in their entirety by reference herein.

### TECHNICAL FIELD

The present invention relates to the display filed, and in particular to an array substrate and method for preparing the same, and a display device.

### BACKGROUND

Referring to FIG. 1, it illustrates the structure of a thin-film transistor (TFT) liquid crystal display panel in the prior art. A TFT liquid crystal display panel mainly consists of a TFT array substrate 101 and a color film (CF) substrate 102. Referring to FIG. 2, FIG. 2 illustrates the cross section of the TFT liquid crystal display panel in FIG. 1. After the cutting process is completed, the TFT array substrate 101 will be slightly larger than the CF substrate 102, and the extra section on TFT array substrate 101 is used for disposing chip on film (COF), which is a carrier of driver ICs 103 (a gate driver IC and a source driver IC). In order to implement signal transmission between driver ICs 103 (between the gate driver ICs and between the gate driver IC and the source driver IC), the TFT array substrate 101 further includes Panel Lead Gate (PLG) wires 104 located in a non-display area.

Referring to FIG. 3, it illustrates the structure of configuration of PLG wires 104 in the prior art. In the prior art, PLG wires 104 are made in the same layer as the gate metal layer of the TFT array substrate, and a plurality of PLG wires are arranged side by side, in which configuration, the width of the non-display area of the TFT array substrate occupied by PLG wires is very large.

As shown in FIGS. 1 and 2, silica gel 105 is coated over COF in order to fix and protect COF. When the width of the area occupied by PLG wires is large, the coated gel can only cover part of the PLG wires, and PLG wires uncovered by silica gel are exposed, which may lead to physical or other damages and cause abnormal display (AD). Damage of PLG is irreparable and is usually hard to visually detect, and thus will not only cause huge waste of company benefits but also result in a bad reputation of the quality image of the company. In addition, when the width of the area occupied by PLG wires is very large, it may also cause low utilization rate of the TFT array substrate, which is undesirable for application of narrow bezel screens.

### SUMMARY

In view of the above, the present invention provides an array substrate and a method for preparing the same, and a display device, which can reduce the width of the non-display area of the array substrate occupied by signal connection wires for connecting a driver IC.

In order to solve the above technical problem, an example of the present invention provides an array substrate, comprising:

a display area and a non-display area, and a plurality of signal connection wires located in the non-display area for connecting driver units, the plurality of the signal connection wires comprising first connection wires electrically connected with the driver units and second connection wires electrically connected with the first connection wires, the second connection wires being arranged at least in two layers, and each layer of the second connection wires being insulated from one another.

Wherein, areas of the array substrate occupied by the second connection wires arranged in different layers at least partially overlap.

Wherein, at least part of the second connection wires arranged in different layers are superimposed.

Wherein, the array substrate further comprises: a plurality of conductive material layers located in the display area, each layer of the second connection wires and one of the conductive material layers being made in a same layer and using a same material.

Wherein, the conductive material layers comprise a gate metal layer and a source-drain metal layer.

Wherein, the conductive material layers include at least two of a gate metal layer, a source-drain metal layer and a transparent conductive layer.

Wherein, the transparent conductive layer comprises a pixel electrode layer.

Wherein, the transparent conductive layer comprises both a pixel electrode layer and a common electrode layer.

Wherein, the array substrate further comprises:

a gate insulating layer located between the gate metal layer and the source-drain metal layer, each layer of the second connection wires being insulated from one another through the gate insulating layer.

Wherein, the first connection wires and the gate metal layer are made in a same layer and using a same material.

Wherein, the array substrate further comprises:

a passivation layer and a pixel electrode layer,

wherein, the second connection wires in a same layer as the gate metal layer are directly electrically connected with the first connection wires;

the second connection wires in a same layer as the source-drain metal layer are connected with the first connection wires through via holes traversing the passivation layer, the second connection wires in the source-drain metal layer and the gate insulating layer and with the aid of transparent connection parts formed in the pixel electrode layer.

Wherein, the first connection wires are arranged in at least two layers, each layer of the first connection wires is insulated from one another, the first connection wires arranged in a plurality of layers are one-to-one corresponding to the second connection wires arranged in a plurality of layers, and the first connection wires and the second connection wires located in a same layer are directly electrically connected.

Wherein, both the first connection wires and the second connection wires in each layer, and one of the conductive material layers are made in a same layer and using a same material.

The present invention further provides a display device, comprising the above mentioned array substrate.

The present invention further provides a method for preparing an array substrate, comprising:

a step of forming a plurality of signal connection wires for connecting driver ICs in a non-display area of the array substrate, wherein the plurality of the signal connection wires comprise first connection wires electrically connected with the driver IC and second connection wires electrically connected with the first connection wires, the second connection wires are arranged at least in two layers, and each layer is insulated from one another.

Wherein, the step of forming a plurality of signal connection wires for connecting driver ICs in a non-display area of the array substrate specifically comprises:

forming a gate metal layer comprising patterns of the first connection wires and second connection wires;

forming a gate insulating layer;

forming an active layer;

forming a source-drain metal layer comprising the pattern of the second connection wires;

forming a passivation layer, and forming via holes traversing the passivation layer, the second connection wires in the source-drain metal layer and the gate insulating layer;

forming a pixel electrode layer comprising transparent connection parts formed in the via holes, the second connection wires in the source-drain metal layer connecting with the first connection wires through the via holes with the aid of the transparent connection parts.

The above technical solution of the present invention has the following beneficial effects:

The solution of the present invention can reduce the width of the non-display area of an array substrate occupied by signal connection wires for connecting a driver IC so that as many as signal connection wires can be covered by silica gel and the risk of damage of signal connection wires can be reduced, and this solution can also increase the low utilization rate of the array substrate and can be applied to narrow-bezel screen technology.

### BRIEF DESCRIPTION OF THE DRAWINGS

FIG. 1 illustrates the structure of a thin-film transistor (TFT) liquid crystal display panel in the prior art;

FIG. 2 illustrates the cross section of the TFT liquid crystal display panel in FIG. 1;

FIG. 3 illustrates the structure of configuration of PLG wires in the prior art;

FIG. 4 illustrates the structure of configuration of signal connection wires in accordance with Example One of the present invention;

FIG. 5 illustrates the structure of configuration of signal connection wires in accordance with Example Two of the present invention;

FIG. 6 illustrates the structure of configuration of signal connection wires in accordance with Example Three of the present invention;

FIG. 7 illustrates the structure of configuration of signal connection wires in accordance with Example Four of the present invention;

FIG. 8 illustrates a layered structure of an array substrate in accordance with Example Four of the present invention;

FIG. 9 illustrates a layered structure of an array substrate in accordance with Example Five of the present invention.

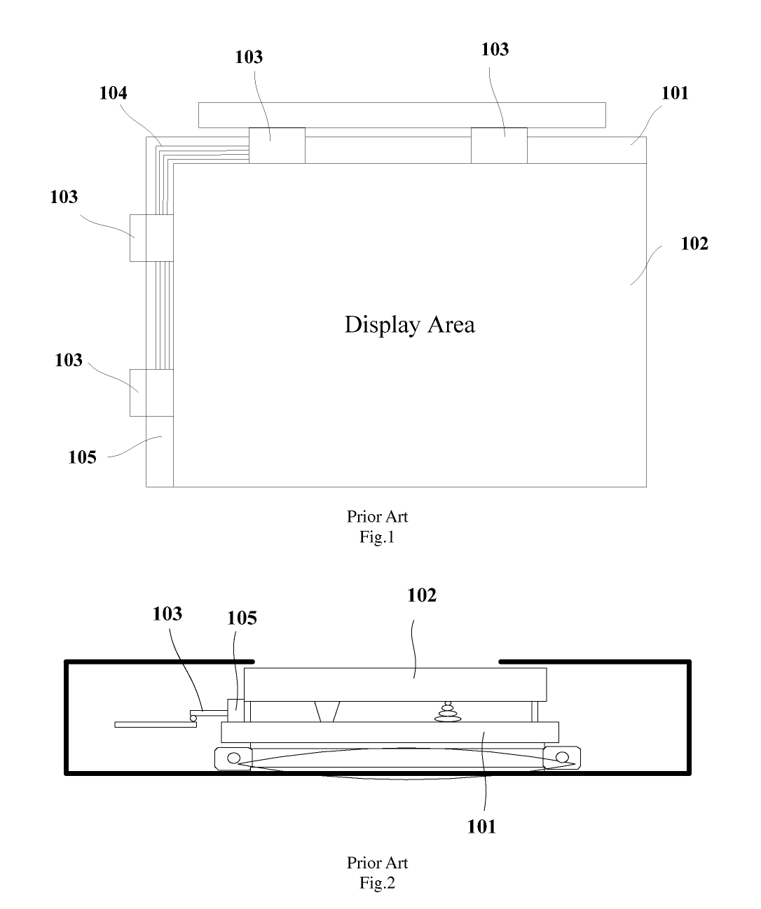

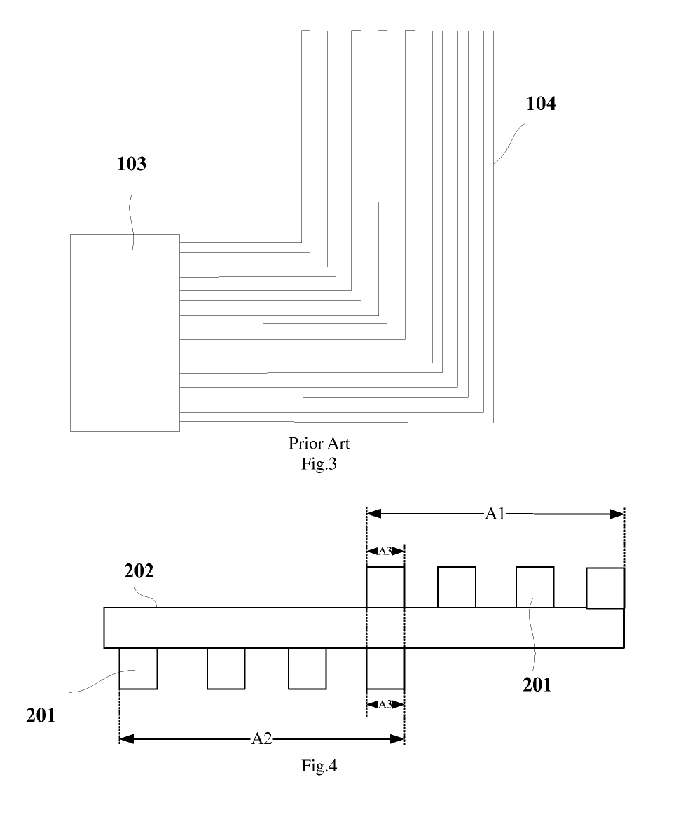

### DETAILED DESCRIPTION

The present invention will be described in detail hereinafter in conjunction with the drawings and specific examples in order to make the technical problem, technical solution and advantages of the present invention clearer.

An example of the present invention provides an array substrate including: a display area and a non-display area, and a plurality of signal connection wires located in the non-display area for connecting driver units and a plurality of conductive material layers located in the display area, the signal connection wires including first connection wires electrically connected with the driver units and second connection wires electrically connected with the first connection wires, the second connection wires being arranged at least in two layers, and each layer of the second connection wires being insulated from one another.

Wherein, areas of the array substrate occupied by the second connection wires arranged in different layers at least partially overlap.

In the prior art, all signal connection wires (i.e., PLG wires) for connecting driver units are disposed on the same layer (gate metal layer), therefore, the width of the non-display area of the array substrate occupied by signal connection wires is very large. In the cases where the numbers, widths and spacing of signal connection wires are all the same, when the signal connection wires are arranged in multiple layers and the areas of the array substrate occupied by the signal connection wires in different layers overlap, the width of the non-display area of the array substrate occupied by the signal connection wires will be reduced, thereby as many as signal connection wires can be covered by silica gel and the risk of damage of signal connection wires can be reduced, and it also increases the low utilization rate of the array substrate and can be applied to narrow-bezel screen technology.

The width of the non-display area of the array substrate mentioned in the example of the present invention refers to the width of the array substrate in the direction perpendicular to the signal connection wires.

In addition, it should be appreciated that there is an insulating layer between different layers of signal connection wires so as to ensure normal transmission of signals.

The method of disposing signal connection wires on the array substrate according to the example of the present invention will be described hereinafter in details.

### Example One

Referring to FIG. 4, it illustrates the structure of configuration of signal connection wires in accordance with Example One of the present invention.

In this example, signal connection wires include first connection wires (not shown) and second connection wires 201, wherein the second connection wires 201 are arranged in two layers, and an insulating layer is disposed between the two layers of the second connection wires 201. An area of the array substrate occupied by the second connection wires 201 in the upper layer is A1, An area of the array substrate occupied by the second connection wires 201 in the lower layer is A2, and the area A1 and the area A2 have an overlapping area A3.

Since there is an overlapping area A3, in the cases where the numbers, widths and spacing of signal connection wires are all the same, the width of the non-display area of the array substrate occupied by the second connection wires arranged in two layers in the example of the present invention is less than the width of the non-display area of the array substrate occupied by the second connection wires arranged in one layer in the prior art, thereby as many as second connection wires can be covered by silica gel and the risk of damage of second connection wires can be reduced, and it also increases the low utilization rate of the array substrate and can be applied to narrow-bezel screen technology.

### Example Two

Referring to FIG. 5, it illustrates the structure of configuration of signal connection wires in accordance with Example Two of the present invention.

In this example, signal connection wires include first connection wires (not shown) and second connection wires 201, wherein the second connection wires 201 are arranged in two layers, and an insulating layer 202 is disposed between the two layers of the second connection wires 201. An area of the array substrate occupied by the second connection wires 201 in the upper layer is A1, an area of the array substrate occupied by the second connection wires 201 in the lower layer is A2, and the area A1 and the area A2 have an overlapping area A4.

Since there is an overlapping area A4, in the cases where the numbers, widths and spacing of signal connection wires are all the same, the width of the non-display area of the array substrate occupied by the second connection wires arranged in two layers in the example of the present invention is less than the width of the non-display area of the array substrate occupied by the signal connection wires arranged in one layer in the prior art, thereby as many as second connection wires can be covered by silica gel and the risk of damage of second connection wires can be reduced, and it also increases the low utilization rate of the array substrate and can be applied to narrow-bezel screen technology.

### Example Three

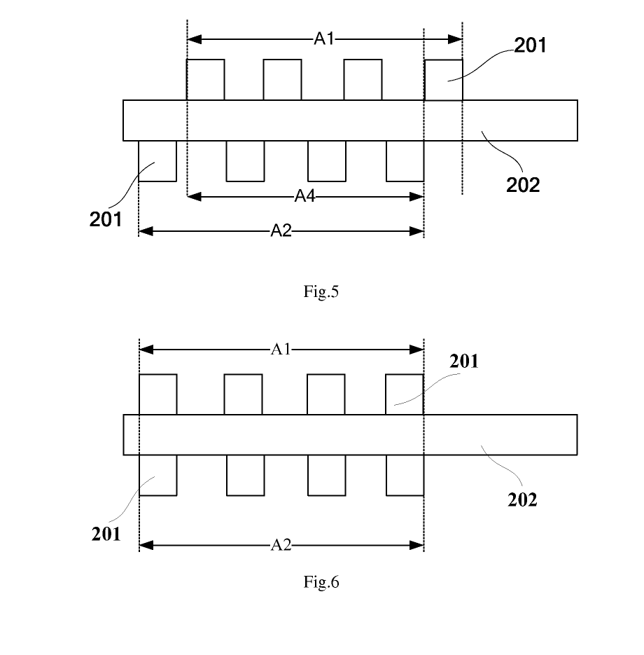

Referring to FIG. 6, it illustrates the structure of configuration of signal connection wires in accordance with Example Three of the present invention.

In this example, signal connection wires include first connection wires (not shown) and second connection wires 201, wherein the second connection wires 201 are arranged in two layers, and an insulating layer is disposed between the two layers of the second connection wires 201. An area of the array substrate occupied by the second connection wires 201 in the upper layer is A1, an area of the array substrate occupied by the second connection wires 201 in the lower layer is A2, the area A1 and the area A2 completely overlap, and the upper and lower layers of the second connection wires 201 are superimposed.

Since there is an completely overlapping area, in the cases where the numbers, widths and spacing of signal connection wires are all the same, the width of the non-display area of the array substrate occupied by the second connection wires arranged in two layers in the example of the present invention is less than the width of the non-display area of the array substrate occupied by the signal connection wires arranged in one layer in the prior art, thereby as many as second connection wires can be covered by silica gel and the risk of damage of second connection wires can be reduced, and it also increases the low utilization rate of the array substrate and can be applied to narrow-bezel screen technology.

In the above various examples, the total number of the second connection wires is 8, and 4 second connection wires are disposed in each layer, i.e., the number of the second connection wires in each layer is the same. Of course, in other examples of the present invention, the numbers of the second connection wires in various layers may be different, for example 3 second connection wires are disposed in the upper layer and 5 second connection wires are disposed in the lower layer.

The above examples are only some specific examples of the present invention, and the second connection wires can also be disposed in other manners, which will not be described one by one here.

In the examples of the present invention, each layer of the second connection wires and one of the conductive material layers can be made in the same layer and using the same material so as to reduce process costs.

The conductive material layers may include at least two of a gate metal layer, a source-drain metal layer and a transparent conductive layer.

The transparent conductive layer may include a pixel electrode layer.

When the array substrate further includes a common electrode, the transparent conductive layer may also include both a pixel electrode layer and a common electrode layer.

Optionally, the conductive material layer includes a gate metal layer and a source-drain metal layer. The second connection wires in the same layer as the gate metal layer may be formed together with the gate electrode and gate line of the gate metal layer through one patterning process. The second connection wires in the same layer as the source-drain metal layer may be formed together with the source-drain electrode and data line in the source-drain metal layer through one patterning process.

Additionally, the array substrate according to the example of the present invention further includes: a gate insulating layer located between the gate metal layer and the source-drain metal layer, each layer of the second connection wires being insulated from one another through the gate insulating layer.

In the example of the present invention, the first connection wires and the gate metal layer can be made in the same layer and using the same material.

In this case, the second connection wires in the same layer as the gate metal layer are directly electrically connected with the first connection wires located in the gate metal layer.

The second connection wires in the same layer as the source-drain metal layer can be connected with the first connection wires located in the gate metal layer through via holes traversing the gate insulating layer and with the aid of a source-drain metal connection part formed in the source-drain metal layer.

The array substrate according to the example of the present invention further includes:

a passivation layer and a pixel electrode layer,

wherein, the second connection wires in the same layer as the source-drain metal layer can also be connected with the first connection wires in the gate metal layer through via holes traversing the passivation layer, the second connection wires in the source-drain metal layer and the gate insulating layer and with the aid of transparent connection parts formed in the pixel electrode layer.

### Example Four

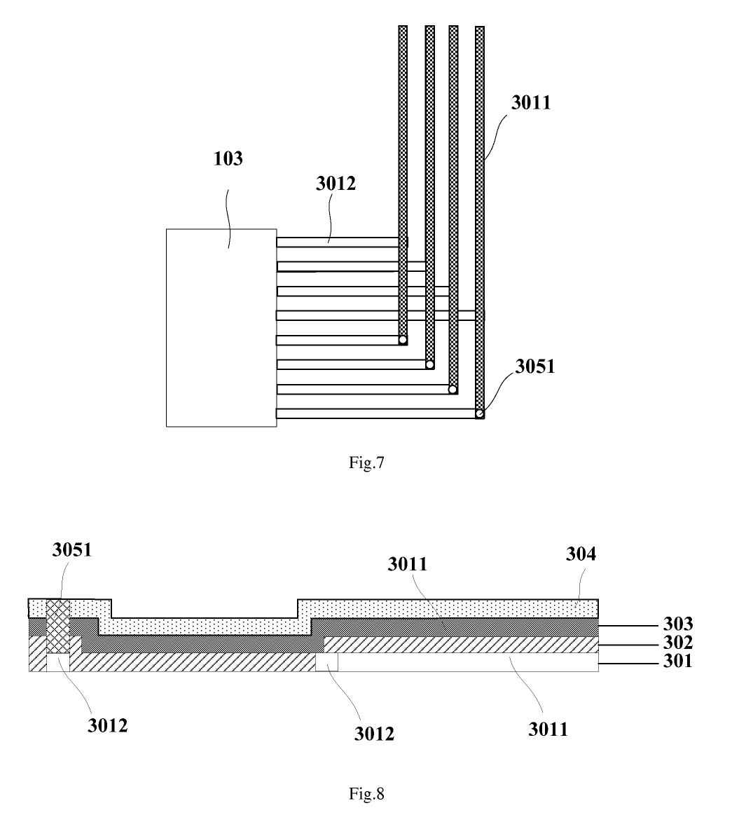

Referring to FIGS. 7 and 8, FIG. 7 illustrates the structure of configuration of signal connection wires in accordance with Example Four of the present invention, and FIG. 8 illustrates a layered structure of an array substrate in accordance with Example Four of the present invention.

The array substrate include: a gate metal layer 301, a gate insulating layer 302, an active layer (not shown), a source-drain metal layer 303, a passivation layer 304, a pixel electrode layer (not shown) and a plurality of signal connection wires disposed in the non-display area of the array substrate for connecting a driver unit 103, the signal connection wires include first connection wires 3012 electrically connected with the driver unit 103 and second connection wires 3011 electrically connected with the first connection wires 3012.

Wherein, part of the second connection wires 3011 are in the same layer as the gate metal layer 301, and another part of the second connection wires 3011 are in the same layer as the source-drain metal layer 303.

The first connection wires 3012 and the gate metal layer 301 are made in the same layer and using the same material.

The second connection wires 3011 in the same layer as the gate metal layer 301 are directly electronically connected with the first connection wires 3012, the second connection wires 3011 in the same layer as the source-drain metal layer 303 are connected with the first connection wires 3012 through via holes traversing the passivation layer 304, the second connection wires 3011 in the source-drain metal layer 303 and the gate insulating layer 302 and with the aid of a transparent conductive connection part 3051 formed in the pixel electrode layer.

Optionally, the via holes are formed together with a via hole for connecting a pixel electrode (not shown) in the pixel electrode layer and a drain electrode (not shown) in the source-drain metal layer 303, so as to reduce process costs.

In this example, the second connection wires 3011 located in the gate metal layer 301 and the second connection wires 3011 located in the source-drain metal layer 303 have the same number, width and spacing, and the second connection wires in the two layers are superimposed.

### Example Five

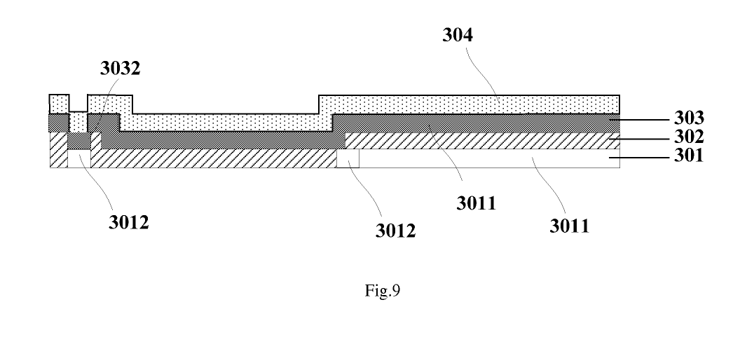

Referring to FIG. 9, FIG. 9 illustrates a layered structure of an array substrate in accordance with Example Five of the present invention. This example differs from the above Example Four in that the second connection wires 3011 in the same layer as the source-drain metal layer 303 are connected with the first connection wires 3012 through via holes traversing the gate insulating layer 302 and with the aid of a source-drain metal connection part 3032 formed in the source-drain metal layer 303.

In the above example, when the second connection wires in the multiple layers are superimposed, the second connection wires with approximate voltages are preferably selected as upper and lower wires, which can avoid electrics problems caused by a huge voltage difference.

In the above example, the first connection wires and the gate metal layer are made in the same layer and using the same material, the second connection wires located in the gate metal layer are directly electrically connected with the first connection wires, and the second connection wires located in other wire material layers are electrically connected with the first connection wires through via holes.

In other examples of the present invention, the first connection wires can also be arranged in at least two layers, each layer of the first connection wires is insulated from one another, the first connection wires arranged in a plurality of layers are one-to-one corresponding to the second connection wires arranged in a plurality of layers, and the first connection wires and the second connection wires located in the same layer are directly electrically connected.

Optionally, both the first connection wires and the second connection wires in each layer and one of the conductive material layers are made in the same layer and using the same material.

The present invention further provides a display device, including an array substrate in any one of the above examples, and the display device may be any product or part having a display function such as a liquid crystal display panel, an electronic paper, an OLED panel, a mobile phone, a tablet computer, a television, a display, a laptop, a digital photo frame, a navigator and so on.

The example of the present invention further provides a method for preparing an array substrate, including:

a step of forming a plurality of signal connection wires for connecting a driver IC in a non-display area of the array substrate, wherein the signal connection wires include first connection wires electrically connected with the driver IC and second connection wires electrically connected with the first connection wires, the second connection wires are arranged at least in two layers, and each layer is insulated from one another.

Optionally, the step of forming a plurality of signal connection wires for connecting a driver IC in a non-display area of the array substrate specifically includes:

forming a gate metal layer including patterns of the first connection wires and second connection wires;

forming a gate insulating layer;

forming an active layer;

forming a source-drain metal layer including a pattern of the second connection wires;

forming a passivation layer, and forming via holes traversing the passivation layer, the second connection wires in the source-drain metal layer and the gate insulating layer;

forming a pixel electrode layer including transparent connection parts formed in the via holes, through which the second connection wires in the source-drain metal layer are connected with the first connection wires with the aid of the transparent connection parts.

Optionally, the via holes are formed together with a via hole for connecting a pixel electrode in the pixel electrode layer and a drain electrode in the source-drain metal layer, so as to reduce process costs.

The above contents are only preferred embodiments of the present invention. It should be appreciated that a person having ordinary skill in the art can make various improvements and modifications without departing from the principle of the present invention. These improvements and modifications, however, shall also be construed as within the protection scope of the present invention.

What is claimed is:

1. An array substrate, comprising:
a display area and a non-display area, and a plurality of signal connection wires located in the non-display area for connecting a driver unit, the plurality of signal connection wires comprising first connection wires electrically connected with the driver unit and second connection wires electrically connected with the first connection wires, the second connection wires being arranged at least in two layers, and each layer of the second connection wires being insulated from one another.

2. The array substrate according to claim 1, wherein, areas of the array substrate occupied by the second connection wires arranged in different layers at least partially overlap.

3. The array substrate according to claim 2, wherein, at least part of the second connection wires arranged in different layers are superimposed.

4. The array substrate according to claim 2, further comprising: a plurality of conductive material layers located in the display area, each layer of the second connection wires and one of the conductive material layers being made in a same layer and using a same material.

5. The array substrate according to claim 3, further comprising: a plurality of conductive material layers located in the display area, each layer of the second connection wires and one of the conductive material layers being made in a same layer and using a same material.

6. The array substrate according to claim 4, wherein, the conductive material layers comprise a gate metal layer and a source-drain metal layer.

7. The array substrate according to claim 4, wherein, the conductive material layers include at least two of a gate metal layer, a source-drain metal layer and a transparent conductive layer.

8. The array substrate according to claim 7, wherein, the transparent conductive layer comprises a pixel electrode layer.

9. The array substrate according to claim 7, wherein, the transparent conductive layer comprises both a pixel electrode layer and a common electrode layer.

10. The array substrate according to claim 6, further comprising:
a gate insulating layer located between the gate metal layer and the source-drain metal layer, each layer of the second connection wires being insulated from one another through the gate insulating layer.

11. The array substrate according to claim 10, wherein, the first connection wires and the gate metal layer are made in a same layer and using a same material.

12. The array substrate according to claim 11, further comprising:
a passivation layer and a pixel electrode layer,
wherein, the second connection wires in a same layer as the gate metal layer are directly electrically connected with the first connection wires;
the second connection wires in a same layer as the source-drain metal layer are connected with the first connection wires through via holes traversing the passivation layer, the second connection wires in the source-drain metal layer and the gate insulating layer and with the aid of transparent connection parts formed in the pixel electrode layer.

13. The array substrate according to claim 2, wherein, the first connection wires are arranged in at least two layers, each layer of the first connection wires is insulated from one another, the first connection wires arranged in a plurality of layers are one-to-one corresponding to the second connection wires arranged in a plurality of layers, and the first connection wires and the second connection wires located in a same layer are directly electrically connected.

14. The array substrate according to claim 3, wherein, the first connection wires are arranged in at least two layers, each layer of the first connection wires is insulated from one another, the first connection wires arranged in a plurality of layers are one-to-one corresponding to the second connection wires arranged in a plurality of layers, and the first connection wires and the second connection wires located in a same layer are directly electrically connected.

15. The array substrate according to claim 14, wherein, both the first connection wires and the second connection wires in each layer, and one of the conductive material layers are made in a same layer and using a same material.

16. A display device comprising the array substrate according to claim 1.

17. A method for preparing an array substrate, comprising:
a step of forming a plurality of signal connection wires for connecting a driver IC in a non-display area of the array substrate, wherein the plurality of the signal connection wires comprise first connection wires electrically connected with the driver IC and second connection wires electrically connected with the first connection wires, the second connection wires are arranged at least in two layers, and each layer is insulated from one another.

18. The method for preparing an array substrate according to claim 17, wherein, the step of forming a plurality of signal connection wires for connecting a driver IC in a non-display area of the array substrate comprises:
forming a gate metal layer comprising patterns of the first connection wires and second connection wires;
forming a gate insulating layer;
forming an active layer;
forming a source-drain metal layer comprising the pattern of the second connection wires;
forming a passivation layer, and forming via holes traversing the passivation layer, the second connection wires in the source-drain metal layer and the gate insulating layer;
forming a pixel electrode layer comprising transparent connection parts formed in the via holes, the second connection wires in the source-drain metal layer connecting with the first connection wires through the via holes with the aid of the transparent connection parts.
